(19) United States
(12) Patent Application Publication
(10) Pub. No.: US 2007/0037349 A1
(43) Pub. Date: Feb. 15, 2007

(54) Method of forming electrodes

(76) Inventors: Martin Gutsche, Dorfen (DE); Harald Seidl, Poering (DE); Peter Moll, Dresden (DE)

Correspondence Address: SLATER & MATSIL LLP, 17950 PRESTON ROAD, SUITE 1000, DALLAS, TX, 75252, US

(21) Appl. No.: 11/526,788

(22) Filed: Sep. 25, 2006

Related U.S. Application Data
(63) Continuation-in-part of application No. 11/079,131, filed on Mar. 14, 2005, now Pat. No. 7,112,487.
(63) Continuation-in-part of application No. 11/112,940, filed on Apr. 22, 2005.

(30) Foreign Application Priority Data
Apr. 30, 2004 (DE) 102004021399.2
Apr. 30, 2004 (DE) 102004021401.8

(51) Int. Cl. H01L 21/8242

(52) U.S. Cl. 438/253

(57) ABSTRACT

To form a semiconductor device, a plurality of upwardly extending conductors can be formed. The conductors extend outward from a surface of a semiconductor body, adjacent ones of the conductors being separated from each other by a separating material. At least one support structure is formed between adjacent ones of the upwardly extending conductors. The support structure is formed of a material different than the separating material. The separating material can be removed and further processing can be performed on the semiconductor device.

This is a continuation-in-part of patent application Ser. No. 11/079,131, which was filed on Mar. 14, 2005 (published as U.S. Patent Application Publication 2005/0245027) and which claims priority to German Application DE 102004021399.2, filed Apr. 30, 2004. This is also a continuation-in-part of patent application Ser. No. 11/112,940, which was filed on Apr. 22, 2005 (published as U.S. Patent Application Publication 2005/0245022) and which claims priority to German application DE 102004021401.8, filed Apr. 30, 2004. Both earlier filed U.S. patent applications and their German counterparts are incorporated herein by reference.

### TECHNICAL FIELD

This invention relates generally to semiconductor devices, and in particular to embodiments to electrodes and methods of forming electrodes.

### BACKGROUND

Although applicable in principle to arbitrary integrated circuits, the present invention and also the problem area on which it is based will be explained with regard to integrated memory circuits, in particular DRAM cells, in silicon technology.

A stacked capacitor array has a multiplicity of stacked capacitors which are preferably arranged regularly. As is known, a stacked capacitor is preferably connected to a transistor downward in order to form a DRAM cell. In the known fabrication of stacked capacitors, in particular of cylindrical stacked capacitors, in a stacked capacitor array, there is the problem that as the aspect ratio of the individual stacked capacitors increases, their mechanical stability decreases. If the aspect ratio of pillarlike or crownlike capacitors increases above a specific value, then the structures become mechanically unstable. In a disadvantageous manner, capacitors may incline toward one another on account of this instability. If two neighboring capacitors incline toward one another to such an extent that they touch one another, a short circuit arises between these two capacitors. Memory errors occur within a stacked capacitor array on account of a short circuit between two capacitors. With a lack of mechanical stability, stacked capacitors may also completely topple over and thus bring about defects within the stacked capacitor array.

This problem has been solved hitherto by keeping the aspect ratio of the individual capacitor below a limit value determined empirically. The capacitance that can be achieved per capacitor is thereby limited, however. In order to further improve the large scale integration of memory circuits, however, it is necessary to increase the capacitance of the respective capacitor per chip area by increasing the aspect ratio.

### SUMMARY OF THE INVENTION

To form a semiconductor device, a plurality of upwardly extending conductors can be formed. The conductors extend outward from a surface of a semiconductor body, adjacent ones of the conductors being separated from each other by a separating material. At least one support structure is formed between adjacent ones of the upwardly extending conductors. The support structure is formed of a material different than the separating material. The separating material can be removed and further processing can be performed on the semiconductor device.

This patent is a continuation-in-part of two co-pending patent applications, which are both incorporated herein by reference. The entirety of details described in the co-pending applications apply here, whether explicitly stated or not.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 diagrammatically depicts a cross-sectional view through a stacked capacitor array according to the invention;

FIGS. 2a-2i diagrammatically depict successive method stages involved in a fabrication method as a first embodiment of the present invention, illustrating the stacked capacitors which adjoin one another in first directions;

FIGS. 3a-3i diagrammatically depict successive method stages of the fabrication method according to the first embodiment of the present invention, illustrating the stacked capacitors which adjoin one another in second directions;

FIGS. 4a, 4b in each case diagrammatically depict an intermediate stage of a fabrication method as a second embodiment of the present invention;

FIG. 5 shows a schematic illustration of a plan view of a stacked capacitor array according to the invention;

FIGS. 6a-6c show schematic illustrations of successive method stages of a fabrication method as a first embodiment of the present invention, the stacked capacitors that are adjacent in first directions being illustrated;

FIGS. 7a-7e show schematic illustrations of successive method stages of the fabrication method according to the first embodiment of the present invention, the stacked capacitors that are adjacent in second directions being illustrated; and

FIGS. 8a-8g show schematic illustrations of successive method stages of a fabrication method as second embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In one aspect, the present invention relates to a stacked capacitor array and a fabrication method for a stacked capacitor array having a multiplicity of stacked capacitors, an insulator keeping at least two adjacent stacked capacitors mutually spaced apart, so that no electrical contact can arise between them and the stacked capacitors are mechanically stabilized.

Embodiments of the present invention can be used with stacked capacitor arrays where the stacked capacitors have a high aspect ratio. An insulator connects at least two adjacent stacked capacitors to one another and thus mechanically stabilizes them mutually. Two stacked capacitors connected by means of the insulator are mechanically stabilized and cannot incline toward one another or tip over. In an array, the insulator connects many or all adjacent stacked capacitors to one another and thus mechanically stabilizes them.

In one particular embodiment, the multiplicity of stacked capacitors is arranged regularly, such that a stacked capacitor having a smaller spacing from the respective adjacent stacked capacitors in specific first directions than in specific second directions, the insulator keeping spaced apart at least two stacked capacitors that are adjacent in the first direction.

In various embodiments, a method for fabricating a stacked capacitor array, which comprises a regular arrangement of a plurality of stacked capacitors, with a stacked capacitor being at a shorter distance from the respectively adjacent stacked capacitor in certain first directions than in certain second directions, with the fabrication method comprising the following method steps: provision of an auxiliary layer stack having first auxiliary layers with a predetermined etching rate and at least one second auxiliary layer with a higher etching rate on a substrate; etching of in each case one hollow cylinder for each stacked capacitor through the auxiliary layer stack in accordance with the regular arrangement, with the auxiliary layer stack being left in place in intermediate regions between the hollow cylinders; isotropic etching of the second auxiliary layers to form widened portions of the hollow cylinders, without any second auxiliary layer being left in place between in each case two hollow cylinders which adjoin one another in the first direction and with a second residual auxiliary layer being left in place between in each case two hollow cylinders which adjoin one another in the second direction; conformal deposition of an insulator layer in order to completely fill the widened portions; deposition of a first electrode layer in the hollow cylinders in order to form the stacked capacitors; filling of the hollow cylinders with a first filling; removal of the first auxiliary layers, the second residual auxiliary layers and the first filling and completion of the stacked capacitor array.

A second embodiment method for fabricating a stacked capacitor array, which comprises a regular arrangement of a plurality of stacked capacitors, with a stacked capacitor being at a shorter distance from the respective adjacent stacked capacitor in certain first directions than in certain second directions, with the fabrication method comprising the following method steps of: provision of an auxiliary layer stack having first auxiliary layers with a predetermined etching rate and at least one second auxiliary layer with a higher etching rate on a substrate; etching of in each case one hollow cylinder for each stacked capacitor through the auxiliary layer stack in accordance with the regular arrangement, with the auxiliary layer stack being left in place in intermediate regions between the hollow cylinders; isotropic etching of the second auxiliary layers to form widened portions of the hollow cylinders, without any second auxiliary layer being left in place between in each case two hollow cylinders which adjoin one another in the first direction and with a second residual auxiliary layer being left in place in each case in a central region between two hollow cylinders which adjoin one another in the second direction; deposition of a first electrode layer in the hollow cylinders, completely filling the widened portions of the hollow cylinders; filling of the hollow cylinders with a first filling, removal of the first auxiliary layers, the second residual auxiliary layers and the first filling; completion of the stacked capacitors and etchback of the stacked capacitors to a level below the widened portions, so that individual stacked capacitors are no longer electrically connected.

In a third embodiment method for fabricating a stacked capacitor array having a regular arrangement of a multiplicity of stacked capacitors, a stacked capacitor having a smaller spacing from the respective adjacent stacked capacitors in specific first directions than in specific second directions: providing a first auxiliary layer on a substrate; providing a respective cylinder for each stacked capacitor in the first auxiliary layer in accordance with the regular arrangement, the first auxiliary layer remaining only in intermediate regions between the cylinders; etching back the first auxiliary layer in an upper region of the intermediate regions; depositing an insulator in the upper region of the intermediate regions; etching back the insulator, so that in each case two stacked capacitors that are adjacent in the first direction remain connected by means of the insulator and so that in each case a hole is formed through the insulator between two stacked capacitors that are adjacent in the second direction; removing the first auxiliary layer by means of the holes formed in the intermediate regions; and completing the stacked capacitor array.

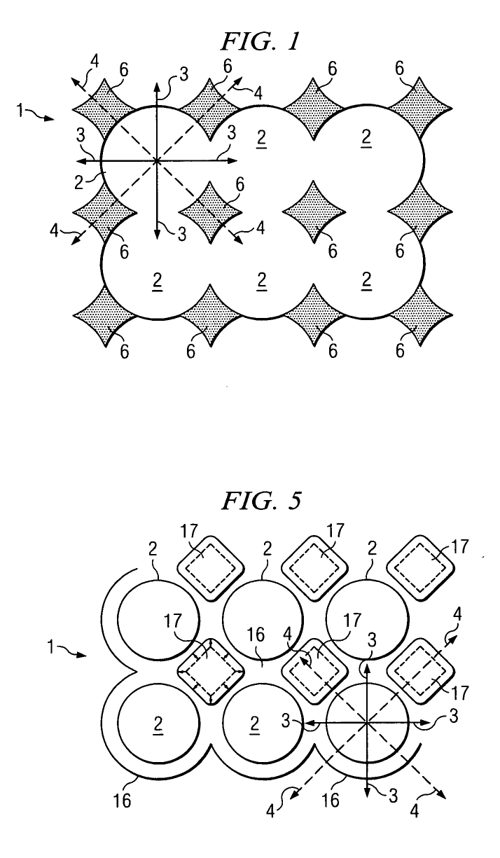

FIG. 1 diagrammatically depicts a plan view in cross section of a stacked capacitor array according to a first embodiment of the invention. In this figure, reference numeral 1 denotes the stacked capacitor array, which has six stacked capacitors 2 in the excerpt that is shown. A stacked capacitor 2 is at a shorter distance from the respectively adjacent stacked capacitors 2 in certain first directions 3 than in certain second directions 4. The regular arrangement of the stacked capacitors 2 in the stacked capacitor array 1 is preferably in the style of a chessboard, with both the first directions 3 and the second directions 4 in each case being oriented perpendicular to one another. The method according to the invention can also be applied to any other regular arrangement.

The figures show that the capacitors 2 each have a circular cross section when viewed from above. This does not need to be the case. For example, in certain embodiments the capacitor electrode could be formed from a hollow cylinder with an elliptical or rectangular cross section.

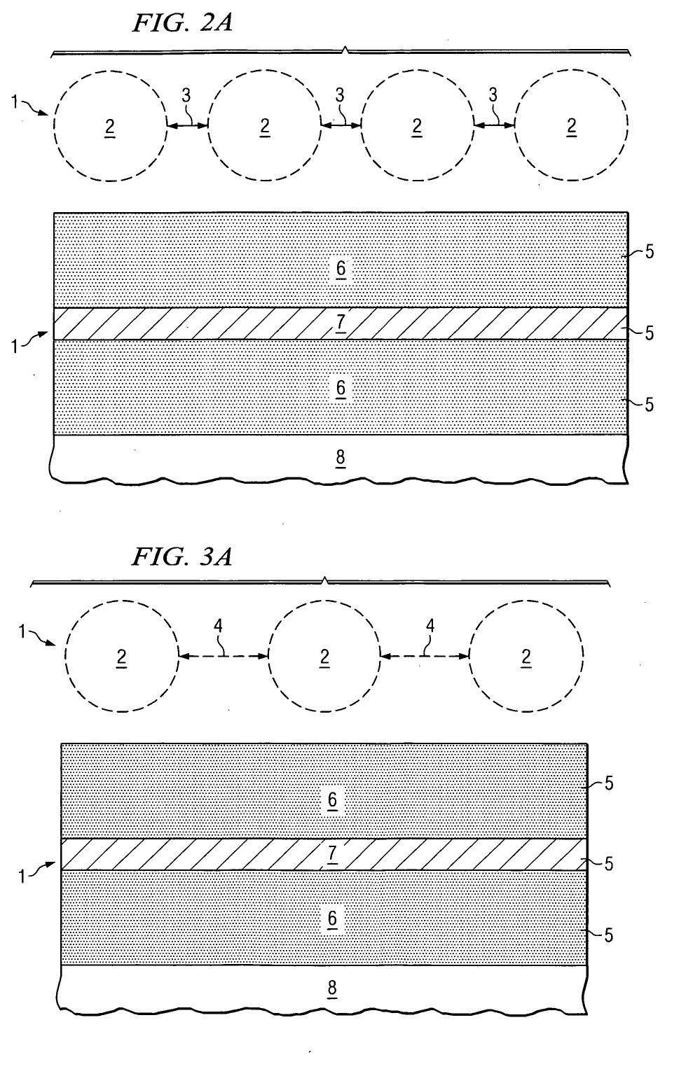

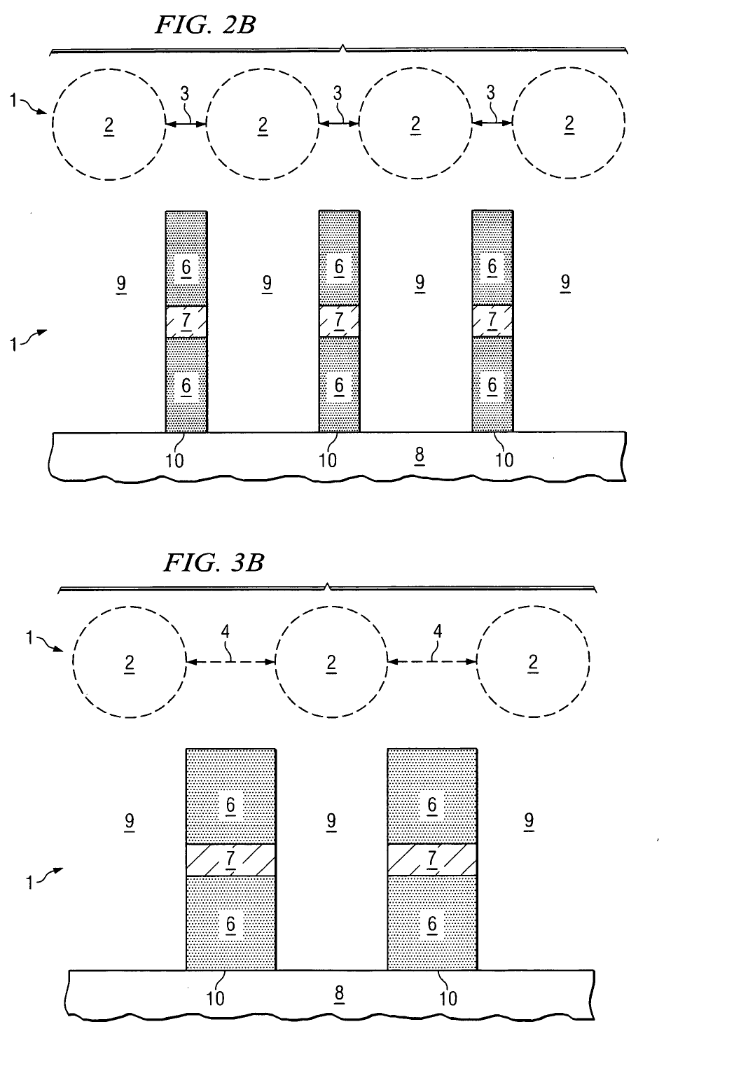

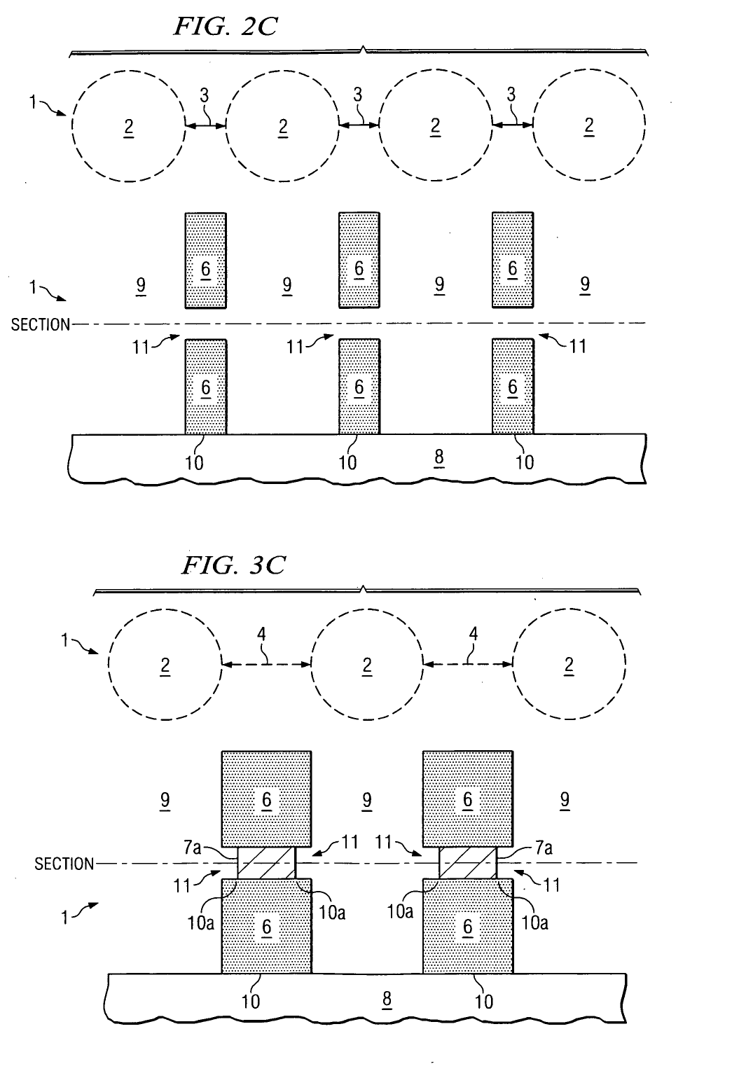

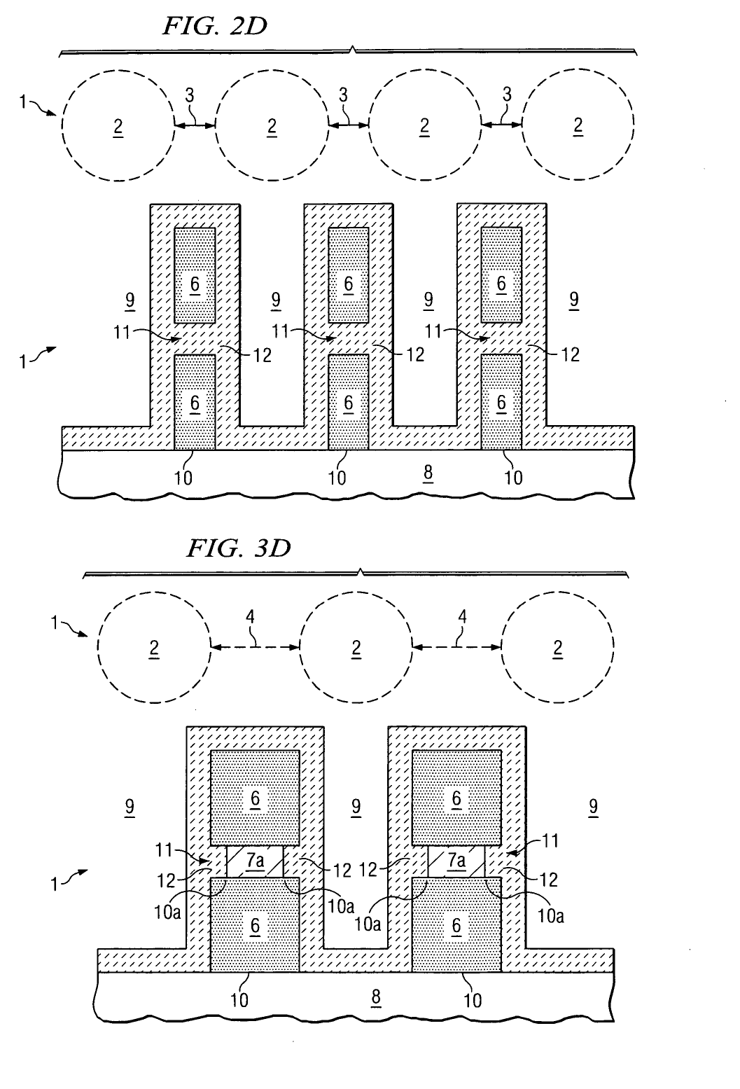

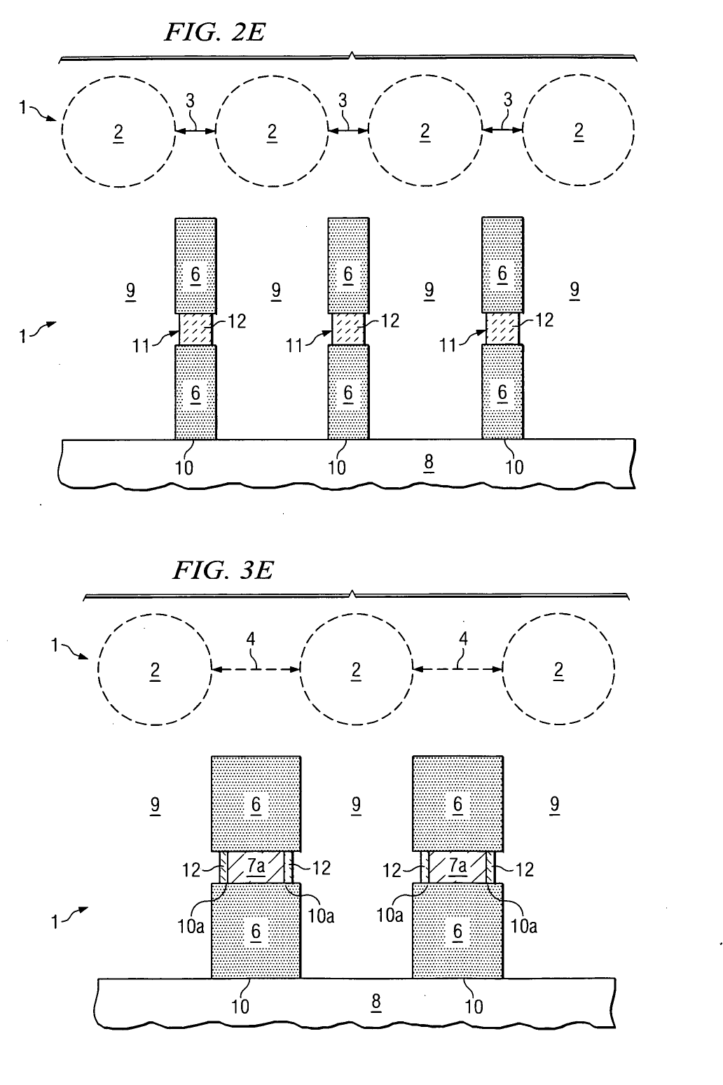

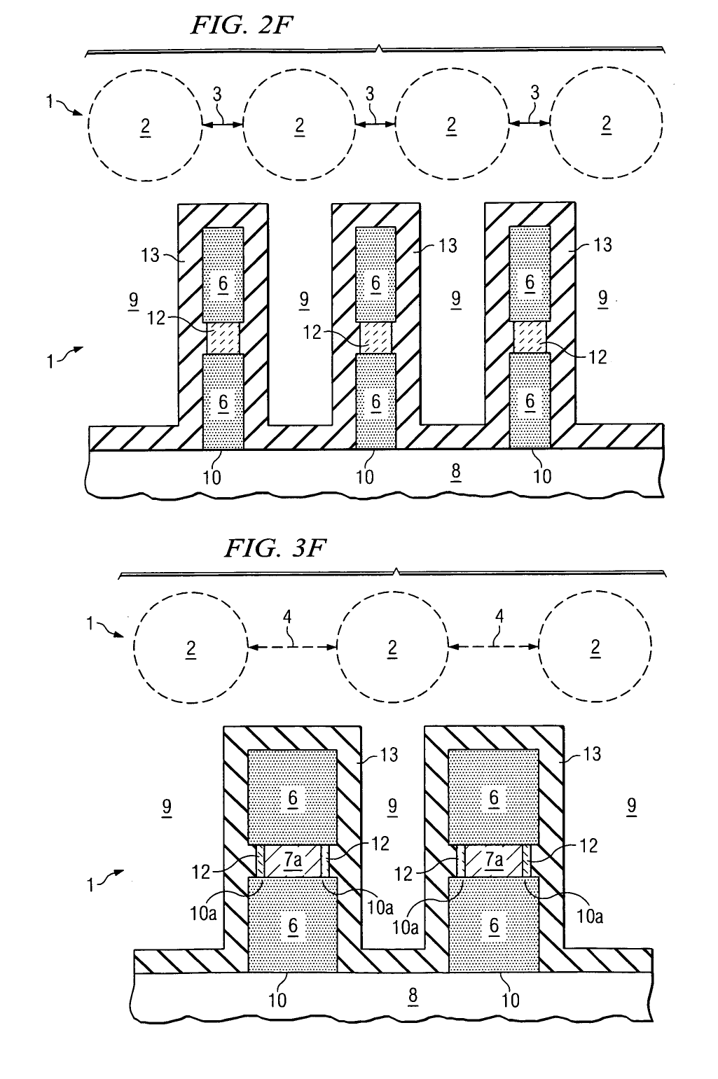

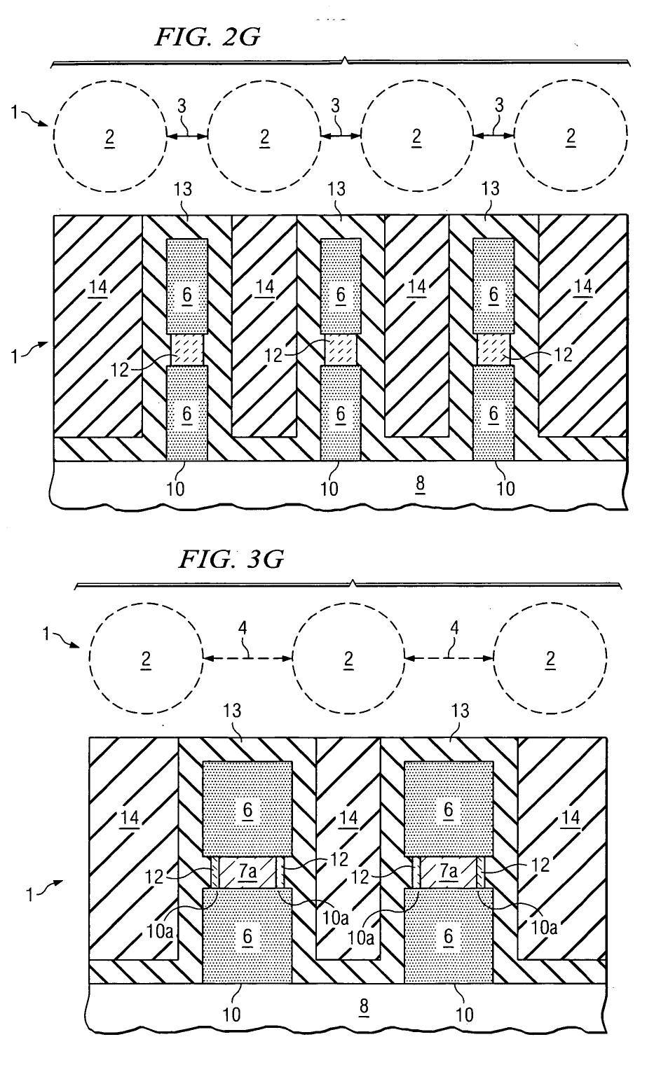

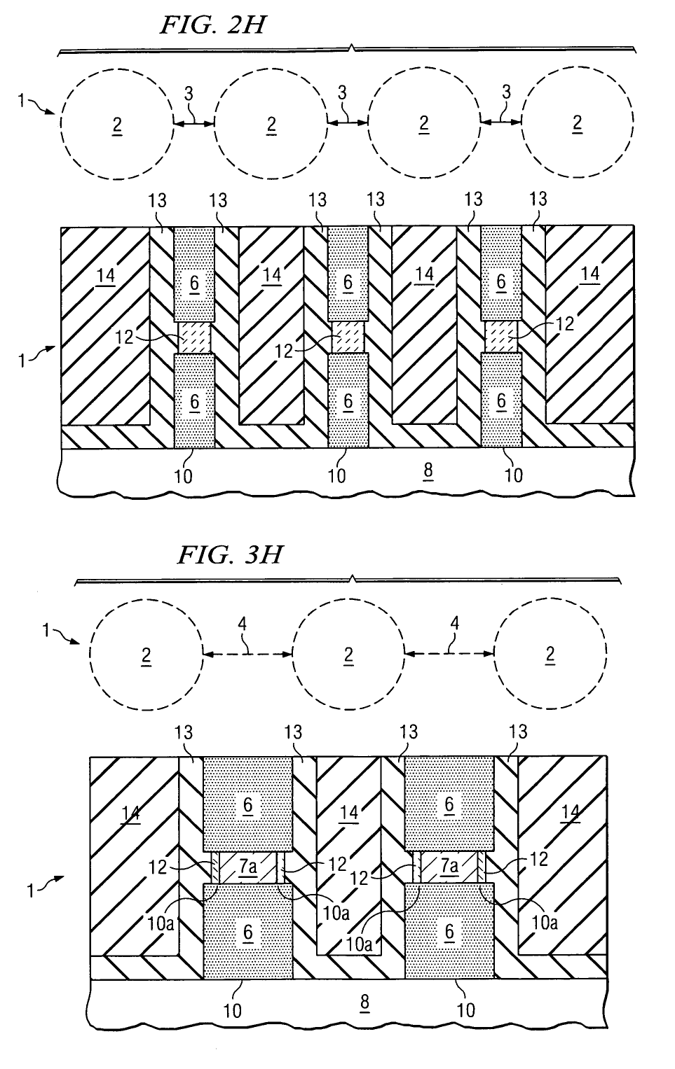

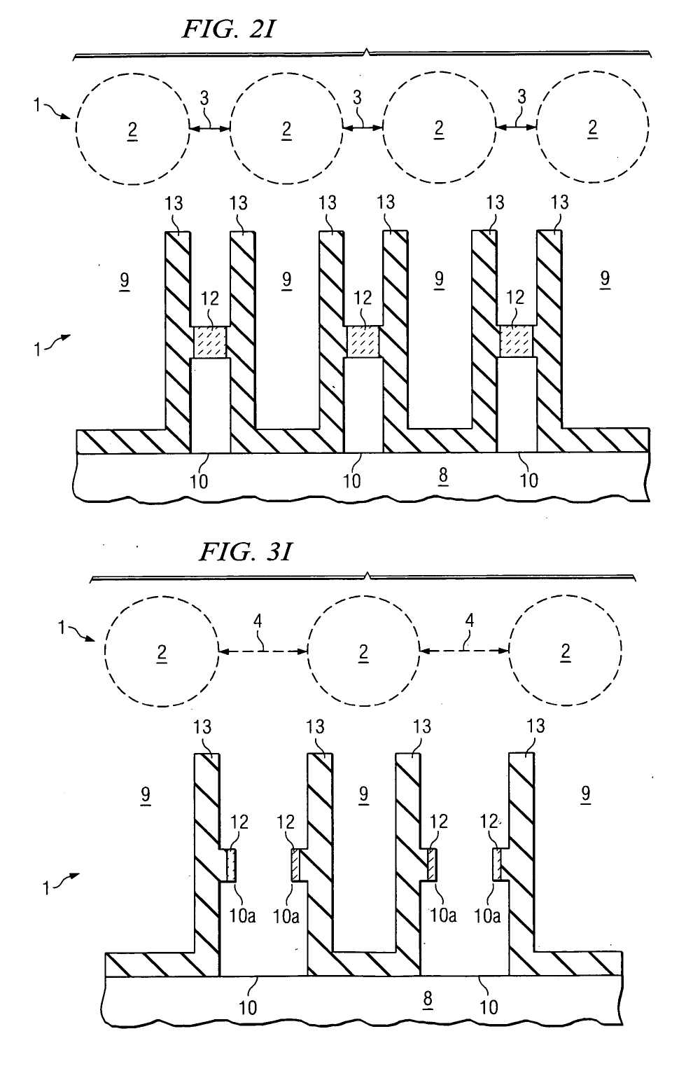

In the second directions 4, two adjacent stacked capacitors 2 are in each case separated by a first auxiliary layer 6. The method stage illustrated in FIG. 1 corresponds to the method stage illustrated in the corresponding FIGS. 2c and 3c.

Apart from FIG. 1, the upper part of all the figures shows a plan view of the respective method stage used to fabricate a stacked capacitor array 1 according to a first embodiment of the invention, while the lower part of each of the figures shows a cross-sectional view of the corresponding method stage.

FIGS. 2a to 2i diagrammatically depict successive method stages of a fabrication method as a first embodiment of the present invention, illustrating the stacked capacitors 2 which adjoin one another in first directions 3. FIG. 2a (and 3a) shows the starting stage of the first embodiment, in which an auxiliary layer stack 5 has been provided on a substrate 8. The auxiliary layer stack 5 comprises a superimposed arrangement of a second auxiliary layer 7 on top of a first auxiliary layer 6. A first auxiliary layer 6 is in turn provided on top of the second auxiliary layer 7.

In one embodiment, the first auxiliary layers 6 have a predetermined etching rate and the second auxiliary layers 7 have a higher etching rate in comparison thereto. For example, the auxiliary layer stack 2 has precisely one second auxiliary layer 7, which has a higher etching rate than the first auxiliary layers 6. In one specific example, the first auxiliary layers 6 are formed by silicon oxide with a predetermined etching rate, and the second auxiliary layer(s) 7 are formed by silicon oxide with a higher etching rate. Silicon oxide is advantageously easy to etch, making the structure simple to fabricate. The second auxiliary layer(s) 7 can alternatively be formed by borophosphosilicate glass (BPSG).

In one particular embodiment, the second auxiliary layer 7 is provided close to the surface, below a thin first auxiliary layer. One advantage of this preferred refinement is that this therefore allows the supporting structure or the insulator layer to be provided very close to the surface.

Analogously to FIGS. 2a-i, FIGS. 3a-i show diagrammatic illustrations of successive method stages involved in a fabrication method of the first embodiment of the present invention, illustrating the stacked capacitors 2 arranged in second directions 4.

FIG. 2b shows a method stage that follows FIG. 2a, illustrated in the first directions 3. FIG. 3b likewise shows the method stage which follows FIG. 2a, but illustrated in the second directions 4. FIGS. 2b and 3b illustrate that in each case one hollow cylinder 9 for each stacked capacitor 2 is etched through the auxiliary layer stack 5 (which includes layers 6 and 7) in accordance with the regular arrangement (cf. FIG. 1), with the auxiliary layer stack 5 being left in place in intermediate regions 10 between the hollow cylinders 9. The etching of the hollow cylinders 9 can be carried out by means of a dry etching process and/or a wet-chemical etching process.

FIGS. 2c and 3c show that the second auxiliary layers 7 are etched back to form widened portions 11 of the hollow cylinders 9, without any auxiliary layer 7 being left in place between in each case two hollow cylinders 9 which adjoin one another in the first direction 3 (FIG. 2c) but with a second residual auxiliary layer 7a being left in place in each case between two hollow cylinders 9 which adjoin one another in the second direction 4 (FIG. 3c). The etching process is isotropic and carried out until there is no longer any second auxiliary layer 7 in the intermediate regions 10 in the first directions 3.

Then, referring now to FIGS. 2d and 3d, an insulator layer 12 is deposited conformally so as to completely fill the widened portions 11 of the hollow cylinders 9. Conformal deposition of the insulator layer 12 is required, since holes or voids in the insulator layer 12 within the widened portions 11 are to be avoided. The thickness of the insulator layer 12 which is to be deposited is at least half the height of the removed second auxiliary layer 7, so that the widened portions 11 are completely filled. In one example, the insulator layer is formed by Si₃N₄ or by Al₂O_{3.}

Referring now to FIG. 3d, it should be noted that the widened portions 11 are filled with the second residual auxiliary layer 7a in a central region 10a of the intermediate regions 10 and with the insulator layer 12 in the remaining regions of the intermediate regions 10.

FIGS. 2e and 3e illustrate that excess material in the insulator layer 12 which has been deposited within the hollow cylinders 9 is removed by means of an etchback process.

Referring now to FIGS. 2f and 3f, a first electrode layer 13 is deposited in the hollow cylinders 9 in order to form the stacked capacitors 2. It should be noted that according to the invention it is not necessary for the first electrode layer 13 to be deposited over the intermediate regions 10, but it is generally inevitable that this will happen for process engineering reasons. The electrode layer is preferably formed by polysilicon or by metal.

FIGS. 2g and 3g show that a first filling 14 is deposited over the first electrode layer 13 in the hollow cylinders 9. The first filling 14 serves as an auxiliary layer.

It is preferable for the electrode layer 13 to be formed by polysilicon or by a metal.

Since the first electrode layer 13 has also been deposited over the intermediate regions 10, it is removed there by means of chemical mechanical polishing or an etchback process, as shown in FIGS. 2h and 3h. Therefore, the individual stacked capacitor electrodes 2 are no longer electrically connected.

It is then possible for all the auxiliary layers, namely the first auxiliary layers 6, the second residual auxiliary layers 7a and the first filling 14, to be removed by means of an etching process. FIG. 3i illustrates that when the second residual auxiliary layer 7a has been removed, the first auxiliary layer 6 beneath it can also be removed. The regions of the first auxiliary layers 6 which are located in the first directions 3 are also removed by means of these holes, which are formed through the removal of the second residual auxiliary layers 7a. FIG. 2i illustrates that said regions of the first auxiliary layer 6 that have been applied to the substrate 8 have been removed and that the first electrode layers 13 of two stacked capacitors which adjoin one another in the first direction 3 are connected by means of the insulator layer 12.

The connection of two stacked capacitors 2 by means of the insulator layer 12 forms the supporting structure which spaces the individual stacked capacitors apart from one another and improves the stability of the stacked capacitors, which may have even a very high aspect ratio.

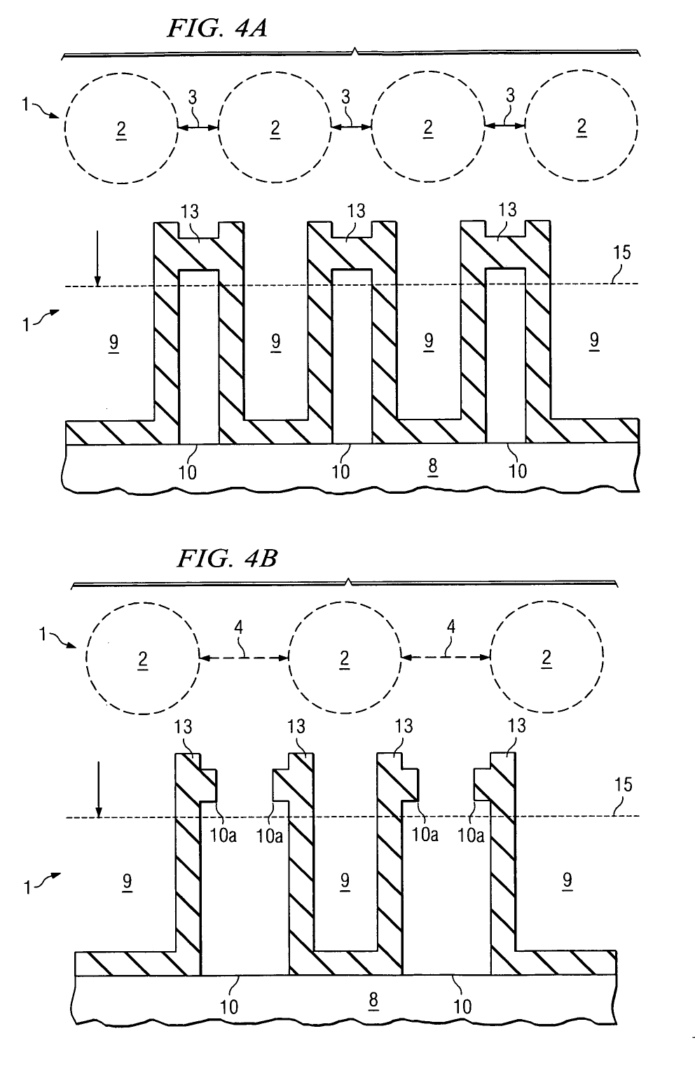

FIGS. 4a and 4b in each case diagrammatically depict an intermediate stage of a fabrication method as a second embodiment of the present invention. FIG. 4a illustrates the stacked capacitors 2 that adjoin one another in first directions 3, whereas FIG. 4b illustrates the stacked capacitors 2 which adjoin one another in second directions 4.

FIGS. 4a and 4b illustrate an intermediate stage for fabrication of a stacked capacitor array 1 according to an alternate embodiment of the invention after the following method steps. An auxiliary layer stack 5 comprising first auxiliary layers 6 with a predetermined etching rate and at least one second auxiliary layer 7 with a higher etching rate was provided on a substrate 8. (See e.g. FIG. 2a.) Then, in each case one hollow cylinder 9 for each stacked capacitor 2 was etched through the auxiliary layer stack 5 in accordance with the regular arrangement, with the auxiliary layer stack 5 being left in place in intermediate regions 10 between the hollow cylinders 9. From this, the second auxiliary layers 7 were etched back isotropically to form widened portions of the hollow cylinders 9, without any second auxiliary layer 7 being left in place between in each case two hollow cylinders 9 which adjoin one another in the first direction 3 and with a second residual auxiliary layer 7a being left in place in a central region 10a of the intermediate regions 10 in each case between two hollow cylinders 9 which adjoin one another in the second direction 4 (as shown in FIGS. 2a to 2c and FIGS. 3a to 3c).

Then, referring now to FIGS. 4a and 4b, a first electrode layer 13 is deposited in the hollow cylinders 9, with the widened portions of the hollow cylinders being completely filled with the electrode layer 13 (not shown). The hollow cylinders 9 are filled with a first filling 14 (not shown). The electrode layer 13 is removed above the intermediate regions 10, and then all the auxiliary layers (6, 7a, 14) can be removed (as shown in FIGS. 2i and 3i and the associated description). The stacked capacitors 2 are then completed (not shown). Openings or holes which may potentially be present are optionally filled by means of a further auxiliary layer, e.g. with a dielectric, so that the mechanical stability of the stacked capacitor array 1 is increased further. Finally, the stacked capacitors 2 are then etched back to a level 15 below the widened portions 11, so that individual stacked capacitors 2 are not electrically connected. It is then possible to provide any desired supporting structure in the intermediate regions 10. Since the stacked capacitors 2 have already been completed and therefore their mechanical stability is ensured, it is optionally also possible to dispense with any supporting structure.

Additional embodiments of the invention will now be described with respect to FIGS. 5-8.

FIG. 5 shows a schematic illustration of a plan view of a stacked capacitor array according to the invention. As before, reference symbol 1 designates the stacked capacitor array, which has six stacked capacitors 2 in the detail from the stacked capacitor array 1 shown. Once again, the stacked capacitor 2 preferably has a smaller spacing from the respective adjacent stacked capacitors 2 in specific first directions 3 than in specific second directions 4. The regular arrangement of the stacked capacitors 2 in the stacked capacitor array 1 is preferably checkered, both the first directions 3 and the second directions 4 in each case being perpendicular to one another. Any other regular arrangement is likewise conceivable.

The plan view according to FIG. 5 of the stacked capacitor array 1 shows the stacked capacitors 2 in each case surrounded by an insulator 16, so that in each case two stacked capacitors 2 that are adjacent in the first direction 3 are connected by means of the insulator 16 and so that in each case a hole 17 is formed through the insulator 16 between two stacked capacitors 2 that are adjacent in the second direction 4. It is shown hereinafter that any auxiliary layers which are situated below the insulator 16 can be removed by means of the holes 17, for instance by the use of isotropic etching methods.

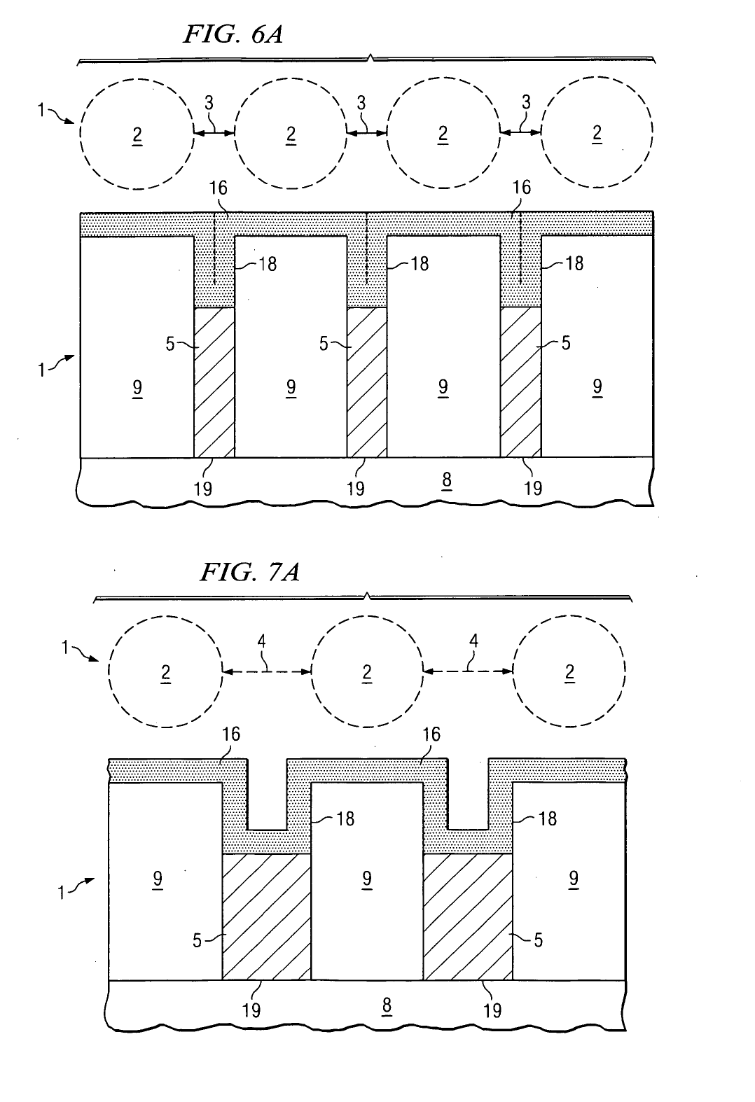

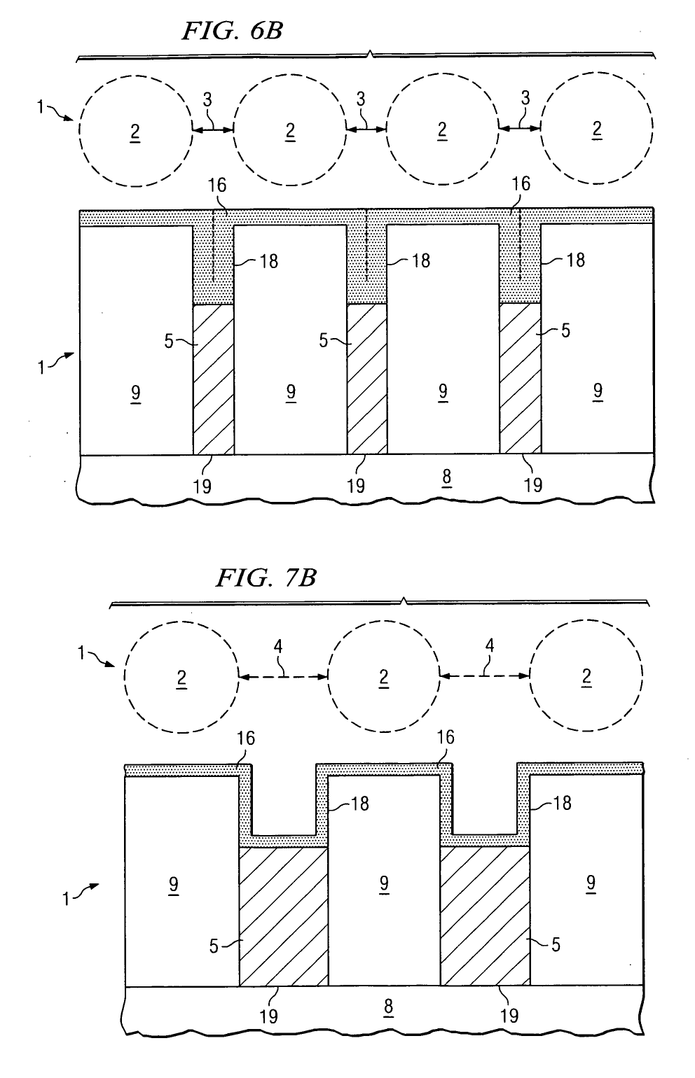

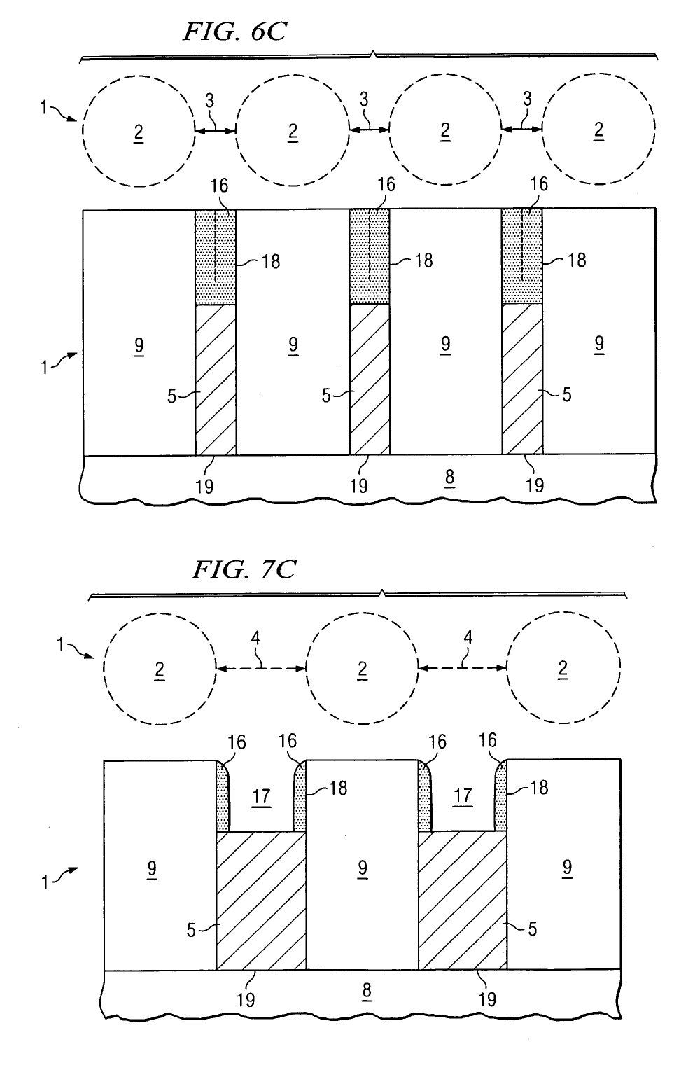

FIGS. 6a-6c show schematic illustrations of successive method stages of a fabrication method as a first embodiment of the present invention, the stacked capacitors 2 that are adjacent in first directions 3 being illustrated.

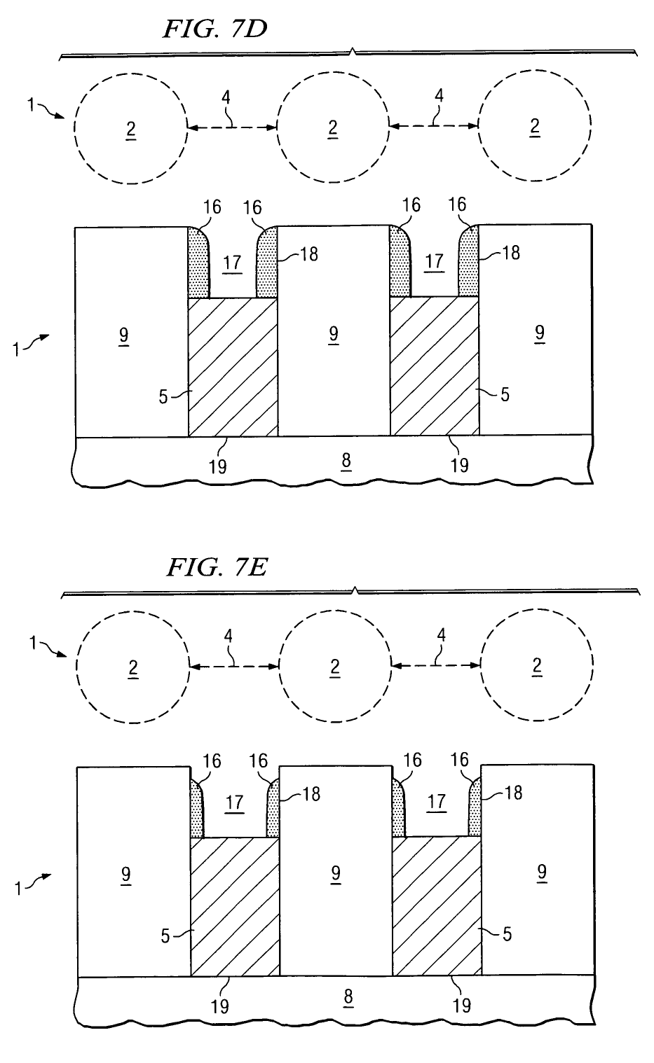

Analogously to this, FIGS. 7a-7c show schematic illustrations of successive method stages of a fabrication method of the first embodiment according to the present invention, the stacked capacitors 2 that are adjacent in second directions 4 being illustrated. FIGS. 7d and 7e in each case show an alternative process sequence to the process sequence illustrated in FIG. 7c.

All of FIGS. 6, 7 and 8 show in the upper region a plan view and in the lower region a cross-sectional view of the respective method stage for fabricating a stacked capacitor array 1 according to the invention.

In this case, FIG. 6a shows the respective stacked capacitor 2 and its respective neighbors or the respective adjacent stacked capacitors 2 in the first directions 3 in a specific method stage. By contrast, FIG. 7a shows the respective stacked capacitor 2 and its respective neighbors in the second directions 4 in the same method stage. The same analogously holds true with regard to the method stage for FIGS. 6b and 7b, and also for FIGS. 6c and 7c.

In specific first directions 3, a stacked capacitor 2 has a smaller spacing from the respective adjacent stacked capacitors 2 than from the stacked capacitors 2 that are adjacent in specific second directions 4.

FIG. 6a illustrates the stacked capacitors 2 in the first direction 3 spaced apart to a smaller extent. The cross-sectional view of FIG. 6a shows that a cylinder 9 for each stacked capacitor 2 is provided in the first auxiliary layer 5 in accordance with the regular arrangement (as shown in FIG. 5). The first auxiliary layer 5 is etched back in an upper region 18 of the intermediate regions 19 between the cylinders 9. An insulator 16 is deposited in the upper region 18 of the intermediate regions 19. FIG. 6a illustrates that the upper region 18 of the intermediate regions 19 is completely filled by the insulator 16 in the first directions 3. By contrast FIG. 7a shows that the upper region 18 of the intermediate regions 19 is not completely filled by the insulator 16 in the second direction 4 on account of the larger spacing. The cylinder 9 may optionally be formed as a solid cylinder or as a hollow cylinder. The cylinder 9 later serves as a first electrode of the capacitor.

In accordance with one embodiment, the first auxiliary layer 5 is formed by silicon or by silicon oxide. One advantage of this embodiment is that both silicon and silicon oxide are readily etchable and it is thus possible to carry out the fabrication of the cylinders for the stacked capacitors in a simple manner.

The first auxiliary layer 5 can be alternatively formed by a superimposition of an undoped silicate glass layer and a borosilicate glass layer. It is known that, in a disadvantageous manner, generally a cone rather than a cylinder arises in the course of dry etching through a specific layer. By virtue of the fact, however, that during the subsequent wet-chemical etching or expansion, the borosilicate glass layer has a higher etching rate with respect to the undoped silicon glass layer, the conical form is avoided and a substantially cylindrical form is formed after etching.

In one embodiment, before the first auxiliary layer is etched back, a first electrode layer is deposited into the hollow cylinders for the purpose of forming crown-type first electrodes for the stacked capacitors and the hollow cylinders are subsequently filled with a first filling. The electrode layer deposited in the hollow cylinder forms a first electrode for the respective stacked capacitor, said electrode having the form of a crown. One advantage of this preferred development is that, as a result of the deposition of the electrode layer and as a result of filling with the first filling, the hollow cylinders are stabilized in such a way as to ensure their mechanical stability during the etching back of the first auxiliary layer and also during subsequent method steps.

The etching of the hollow cylinders is carried out by means of a dry etching process and/or a wet-chemical etching process. Etching of the hollow cylinders is advantageously carried out by means of a combined sequence of both processes.

FIGS. 6b and 7b show that the insulator 16 is partly etched back by means of an isotropic etching process. In accordance with FIGS. 6c and 7c, the insulator 16 is etched back by means of an anisotropic etching process, so that the insulator 16 remains in the upper region 18 of the intermediate regions 19 in the first directions 3 (as shown in FIG. 6c) and so that in each case a hole 17 is formed through the insulator 16 between two stacked capacitors 2 that are adjacent in the second direction 4 (as shown in FIG. 7c).

The etching back of the insulator 10 can be carried out by means of an anisotropic and/or isotropic etching process. One advantage of this preferred development is that the thickness of the insulator can be set as desired through the variable use of isotropic and anisotropic etching processes.

The first auxiliary layer 5 is subsequently removed by means of the holes 17 formed below the upper region 18 of the intermediate regions 19 (not shown). The stacked capacitor array 1 is finally completed by deposition of a dielectric and counterelectrode.

FIGS. 7d and 7e in each case show an alternative process sequence to the process sequence illustrated in FIG. 7c. According to FIG. 7d, the etching of the insulator 16 is carried out exclusively by means of an anisotropic etching process, as a result of which the insulator 16 remains thicker on the vertical regions of the upper region 18 of the intermediate regions 19. By contrast, in accordance with FIG. 7e, an isotropic etching process is carried out after the anisotropic etching, the insulator 16 being made significantly thinner on the vertical regions of the upper region 18 of the intermediate regions 19. In summary, it should be noted that, by means of the variable use of isotropic and anisotropic etching processes, the thickness of the insulator 16 can be set arbitrarily in order to avoid contact between the individual stacked capacitors 2. The insulator 16 may be completely removed by means of the holes 17 in the second directions 4, whereas in the first directions 3 the insulator 16 remains for spacing apart the stacked capacitors 2 that are adjacent in the first direction 3.

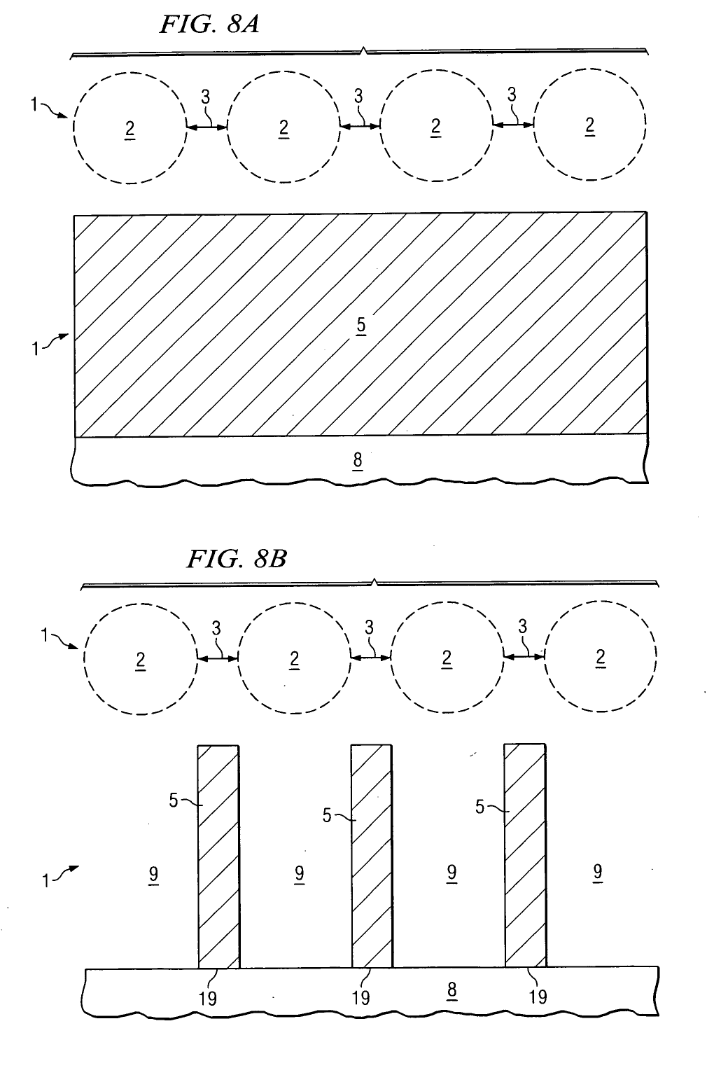

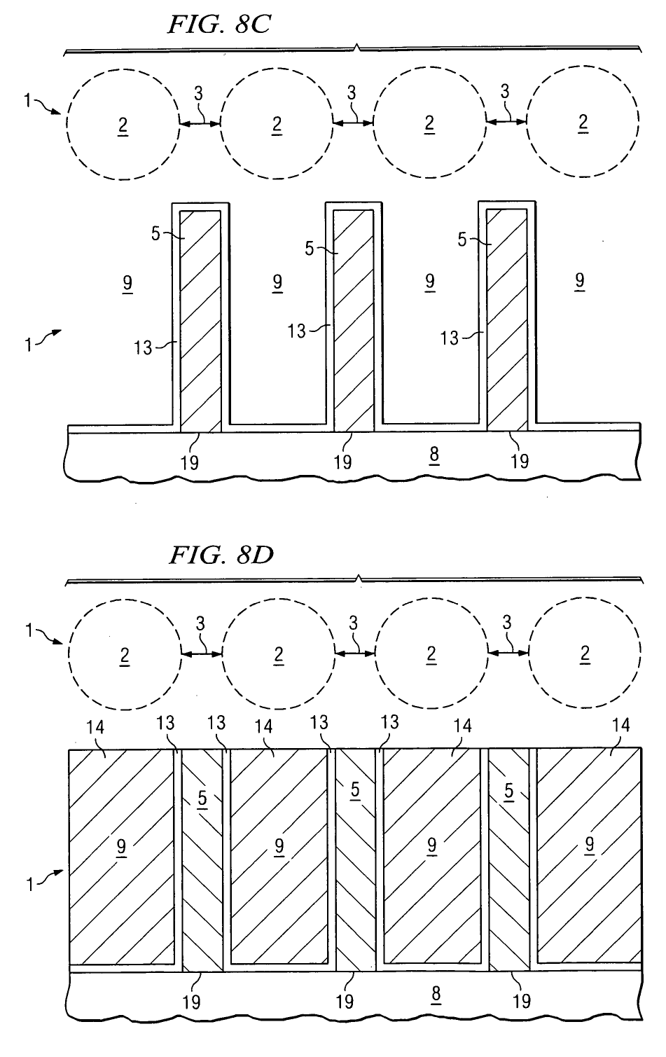

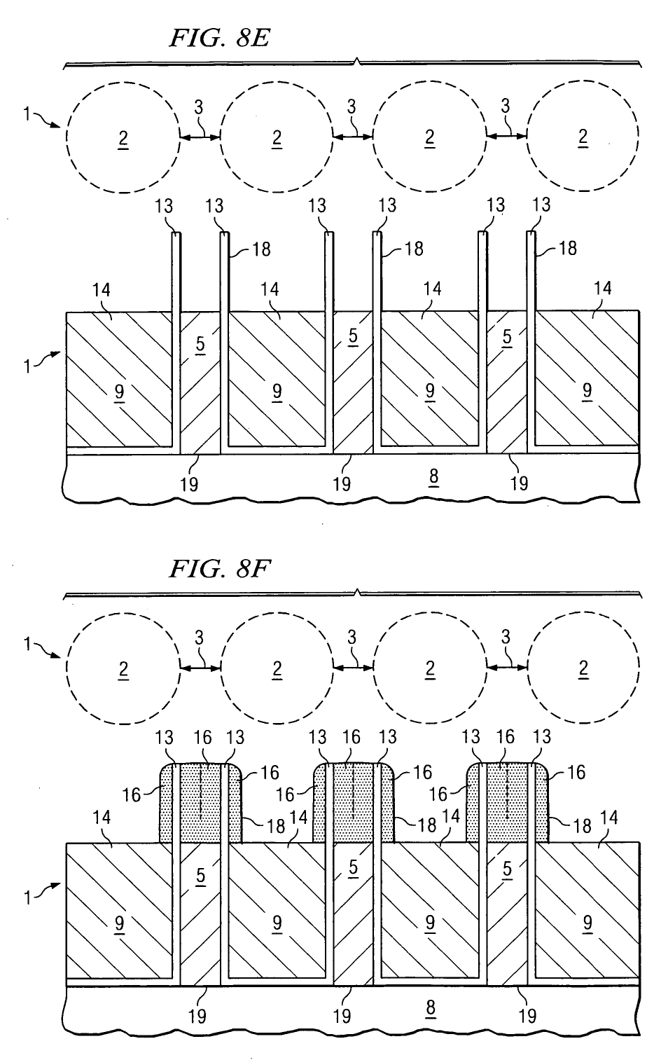

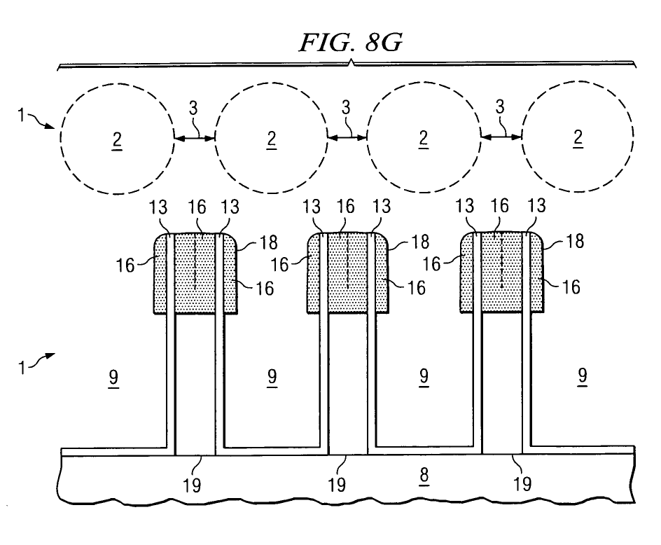

FIGS. 8a-8g show schematic illustrations of successive method stages of a fabrication method as another embodiment of the present invention. These figures illustrate the respective stacked capacitors 2 and the adjacent stacked capacitors 2 exclusively in the first directions 3.

FIG. 8a shows that a first auxiliary layer 5 is provided on a substrate 8. FIG. 8b illustrates that a respective hollow cylinder 9 is provided for each stacked capacitor 2 in the first auxiliary layer 5 in accordance with the regular arrangement (as shown in FIG. 5). The first auxiliary layer 5 remains only in intermediate regions 19 between the hollow cylinders 9.

In accordance with FIG. 8c, a first electrode layer 13 is deposited into the hollow cylinders 9 for the purpose of forming the stacked capacitors 2. Referring to FIG. 8d, after the deposition of the electrode layer 13, a first filling 14 is filled above that into the hollow cylinders 9. The first filling 14 is preferably a dielectric formed by a silicate glass, by way of example. The surface is then planarized. The first filling advantageously fulfills the function of increasing stability during subsequent planarization processes (etching back processes, chemical mechanical polishing).

FIG. 8e shows that both the first auxiliary layer 5 in the intermediate regions 19 and the first filling 14 in the hollow cylinders 9 are etched back in an upper region 18. Referring to FIG. 8f, an insulator 16 is deposited in the upper region 18 both in the intermediate regions 19 and on the electrode layer 13 within the hollow cylinders 9. For example, the insulator can be formed by silicon nitride or by aluminum oxide.

In accordance with an alternative embodiment, the insulator is deposited only on the outside around the cylinder. In an advantageous manner, by virtue of the fact that no insulator is deposited inside the cylinder for the stacked capacitor, the area of the capacitor and thus the capacitance of the capacitor are increased. In accordance with another embodiment, the insulator is deposited on the outside around the cylinder and on the inside. One advantage of this preferred development is that the processing of the stacked capacitor array is thus simplified. Simplifying the processing saves costs. In accordance with certain other embodiments, the insulator surrounds the corresponding stacked capacitor only in insulating fashion and does not connect two adjacent stacked capacitor to one another.

The insulator 16 is subsequently etched back by means of an anisotropic and/or isotropic etching process, so that, on the one hand, in each case the first filling 14 is uncovered upward and, on the other hand, in each case a hole 17 (not shown) is formed through the insulating layer 16 between two stacked capacitors 2 that are adjacent in the second direction 4 (see FIG. 7c). The insulator 16 has the function of spacing apart the individual adjacent stacked capacitors 2 from one another, so that the latter do not touch one another and, consequently, no electrical contact can arise between two stacked capacitors 2 and so that the mechanical stability is increased.

Referring to FIG. 8g, the auxiliary layer 5 is removed by means of the holes 17 (not shown), which are to be seen exclusively in the second direction 4 (see FIG. 7d and FIG. 5). The first filling 14 is removed as well. The stacked capacitor array 1 is finally completed: deposition of the dielectric and the counterelectrode.

Although the present invention has been described above on the basis of preferred exemplary embodiments, it is not restricted thereto, but rather can be modified in diverse ways.

By way of example, it is not always necessary for the insulator to connect to one another two stacked capacitors that are adjacent in a direction spaced apart to a smaller extent. It is also possible for each stacked capacitor only to be surrounded with a ring comprising the insulator so that, in the case of stacked capacitors getting closer to one another, exclusively the rings comprising the insulator touch one another and no electrical contact can therefore arise between two stacked capacitors. Furthermore, the selection of the materials for the layers used is only by way of example; many other materials are conceivable and can be used.

One advantage of embodiments of the present invention is that the insulator insulates two adjacent stacked capacitors from one another such that no electrical contact can arise between them even if they incline toward one another. Short circuits between the adjacent stacked capacitors are thus avoided. Therefore, in accordance with preferred embodiments, the insulator keeps many or all adjacent stacked capacitors spaced apart.

Moreover, the connection of the individual stacked capacitors improve the mechanical stability of the individual stacked capacitors even with a high aspect ratio. A further advantage resides in the fact that the height at which the supporting structures or the insulator layer are generated can be set freely as desired by suitable selection of the layer thicknesses and of the number of first and second auxiliary layers of the auxiliary layer stack. Therefore, the position or height of the insulator layer can be varied as desired. A further advantage is that it is not imperative that an insulator layer be used to space apart the stacked capacitors if the electrode layer itself serves as a supporting structure and the stacked capacitors are etched back to below the level of the supporting structure after they have been completed.

In another embodiment, the hollow cylinder described above can be formed as a solid cylinder which consists of an electrode material. The solid cylinder is then used as an electrode of the capacitor. One advantage of this preferred refinement is that the fabrication method according to the invention is also suitable for solid cylinders, allowing very large scale integration of the memory circuits. Accordingly, the solid cylinder may be elliptical or rectangular in cross section. One advantage of these preferred developments is that the fabrication method according to the invention can be used variably both for hollow and for solid cylinders or for a combination of the two.

Although the present invention has been described above on the basis of preferred exemplary embodiments, it is not restricted to these embodiments, but rather can be modified in various ways. For example, the choice of materials for the layers used is only an example, and many other materials are conceivable and may be employed.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a semiconductor device, the method comprising:
forming a plurality of conductors extending outward from a surface of a semiconductor body, adjacent ones of the conductors being separated from each other by a separating material;
forming at least one support structure between adjacent ones of the extending conductors, the support structure spaced from the surface of the semiconductor body and also being spaced from a plane that crosses an uppermost portion of the plurality of conductors, the support structure being formed of a material different than the separating material;
removing the separating material; and
performing further processing on the semiconductor device.

2. The method of claim 1, wherein forming a plurality conductors comprises forming a plurality of upwardly extending cylindrical conductors.

3. The method of claim 2, wherein forming a plurality conductors comprises forming a plurality of capacitor plates.

4. The method of claim 1, wherein performing further processing includes filling spaces between the adjacent ones of the conductors with an insulating material.

5. A method of forming a semiconductor device, the method comprising:
forming a plurality of conductors extending outward from a surface of a semiconductor body, adjacent ones of the conductors being separated from each other by a separating material;
forming at least one support structure between adjacent ones of the extending conductors, the support structure being formed of a material different than the separating material;
removing the separating material;
filling spaces between the adjacent ones of the conductors with an insulating material; and
removing the at least one support structure after filling the spaces between the adjacent ones of the conductors with an insulating material.

6. The method of claim 5, wherein the conductors and the at least one support structure are formed simultaneously from the same material.

7. A method of forming a semiconductor device, the method comprising:
providing a substrate;
providing a regular electrode arrangement including a plurality of electrodes, an insulating layer and a separating layer being provided between the electrodes of the regular electrode arrangement, the insulating layer being arranged above the separating layer;
etching holes in the insulating layer thereby leaving remaining portions of the insulating layer adjacent at least portions of the electrodes; and
removing the separating layer selectively with respect to the remaining portions of the insulating layer.

8. The method of claim 7, wherein the remaining portions of the insulating layer form a mechanical connection between at least two electrodes.

9. The method of claim 7, wherein the electrodes comprise tube-shaped electrodes.

10. The method of claim 7, further comprising forming an array of stacked capacitors using the regular arrangement of electrodes such that each electrode comprises one plate of one of the stacked capacitors.

11. A method of a manufacturing an electrode arrangement, the method comprising:
forming a material layer;
removing portions of the material layer to form openings;
forming a conductive layer along sidewalls and a bottom surface of the openings in the material layer thereby forming the plurality of electrodes;
etching back the material layer between the electrodes; and
forming an insulating layer between the electrodes over remaining portions of the material layer.

12. The method of claim 11, wherein forming the insulating layer comprises conformally depositing the insulating layer and wherein etching holes in the insulating layer comprises etching back the insulating layer to leave sidewalls along at least portions of an outer surface of the sidewalls.

13. The method of claim 12, further comprising thinning an upper surface of the insulating layer prior to etching back the insulating layer.

14. The method of claim 12, wherein etching back the insulating layer comprises isotropically etching the insulating layer.

15. The method of claim 11, further comprising:
filling the openings with a filling material after forming the conductive layer but before etching back the material layer;
wherein etching back the material layer further comprises etching back the filling material.

16. A method of forming a semiconductor device, the method comprising:
providing a substrate;
forming a first layer over the substrate;
patterning and etching at least two trench structures in the first layer;
depositing an electrode layer over the at least two trench structures;
filling the trench structures with a second layer;
etching and planarizing the second layer and the electrode layer such that portions of the electrode layer are removed from a top surface of the first layer;
etching the first layer to expose side surfaces of the upper ends of the first electrode layer;
depositing a material over the side surfaces of the upper ends of the first electrode layer; and
removing the first and second layers.

17. The method of claim 16, wherein patterning and etching the at least two trench structures comprises patterning and etching a first trench structure, a second trench structure and a third trench structure, wherein the first trench structure is spaced from the second trench structure by a first distance and the first trench structure is spaced from the third trench structure by a second distance that is greater than the first distance.

18. The method of claim 17, wherein removing the first and second layers comprises leaving portions of the deposited material at the side surfaces of the upper ends of the first electrode layer such that a first portion of the deposited material extends between a portion of the first electrode layer in the first trench structure and a portion of the first electrode layer in the second trench structure.

19. The method of claim 16, wherein etching the first layer further comprises etching the second layer to expose opposite side surfaces of the upper ends of the first electrode layer.

20. The method of claim 16, further comprising, after removing the first and second layers, forming a plurality of stacked capacitors, each stacked capacitor including a first plate formed from the electrode layer.

21. The method of claim 16, wherein depositing a material over the side surfaces of the upper ends of the first electrode layer comprises depositing an insulating material.

22. The method of claim 16, wherein depositing a material over the side surfaces comprises conformally depositing a layer of the material and anisotropically etching back the layer of the material.

23. A method of forming a semiconductor device, the method comprising:
forming a first layer of a first material over a semiconductor substrate:
forming a second layer of a second material over the first layer;
forming a third layer of the first material over the second layer;
etching a plurality of openings, each opening extending through the third layer, the second layer and at least a portion of the first layer;
removing portions of the second layer selectively with respect to the first and third layers to leave spaces between the first and third layers;
forming a spacer material in the spaces between the first and third layers;
forming a plurality of electrodes by forming a conductive layer lining sidewalls and a bottom surface of each opening; and
removing remaining portions of the first, second and third layers leaving the spacer material between adjacent ones of the plurality of electrodes.

24. The method of claim 23, wherein forming the plurality of electrodes comprises:
forming the conductive layer lining the sidewalls and bottom surface of each opening and overlying an upper surface of the third layer;
filling the openings with a sacrificial material; and
planarizing an upper surface to remove portions of the conductive layer that overlie the upper surface of the third layer;
wherein removing remaining portions of the first, second and third layers further comprises removing the sacrificial material.

25. The method of claim 23, wherein forming a spacer material in the spaces between the first and third layers comprises:
lining the openings with an insulating layer, the insulating layer being formed in regions between the first and third layers where the second layer was selectively removed; and
removing portions of the insulating layer that are not within the spaces between the first and third layers.

26. The method of claim 23, wherein forming a spacer material in the spaces between the first and third layers comprises forming the conductive layer in the spaces between the first and third layers.

27. The method of claim 26, further comprising, after removing remaining portions of the first, second and third layers, forming a plurality of stacked capacitors, each stacked capacitor including a first plate formed from one of the electrodes, the method further comprising removing the spacer material after at least the plurality of stacked capacitors are at least partially formed.

28. The method of claim 27, wherein removing the spacer material comprises removing an upper region of the conductive layer by a distance that extends beyond the location of the spacers.

29. The method of claim 23, further comprising, after removing remaining portions of the first, second and third layers, forming a plurality of stacked capacitors, each stacked capacitor including a first plate formed from one of the electrodes.

30. A semiconductor device, comprising:
a substrate with an upper surface;
at least two electrodes that extend over the upper surface of the substrate, wherein the at least two electrodes are part of a capacitor array that includes a regular arrangement of stacked capacitors, each stacked capacitor in the array being spaced from a first other stacked capacitor by a first distance and being spaced from a second other stacked capacitor by a second distance that is shorter than the first distance;
a separating material between the at least two electrodes; and
a supporting structure between the at least two electrodes, the supporting structure keeping the at least two electrodes apart, the supporting structure being formed from a different material than the separating material.

31. The semiconductor device of claim 30, wherein the supporting structure extends completely between each stacked capacitor and the second other stacked capacitor but not completely between each stacked capacitor and the first other stacked capacitor.

32. The semiconductor device of claim 30, wherein the separating material comprises a first insulating material and the supporting structure comprises a second insulating material.

33. The semiconductor device of claim 30, wherein the regular arrangement comprises a chessboard-like arrangement such that each stacked capacitor is spaced from its associated first other stacked capacitor in a first direction and from its associated second other stacked capacitor in a second direction, wherein the first direction is perpendicular to the second direction.

34. The semiconductor device of claim 30, wherein each stacked capacitor includes an electrode that is formed from a hollow cylinder with a circular, an elliptical or rectangular cross section.

35. The semiconductor device of claim 30, wherein the capacitor array is part of an integrated memory circuit.

36. The semiconductor device of claim 35, wherein the capacitor array is part of a dynamic random access memory (DRAM).

37. A capacitor arrangement, comprising
a semiconductor body;
a plurality of capacitors arranged over the semiconductor body in a regular pattern, the plurality of capacitors having a first electrode extending into a first direction perpendicular to the substrate surface, a second electrode, and a dielectric layer disposed between the first and the second electrode; and
a supporting structure disposed between the first electrodes of neighboring capacitors, the supporting structure comprising a plurality of openings arranged in a regular pattern, wherein the pattern of the openings of the supporting structure is shifted relative to the pattern of the capacitors.

38. The capacitor arrangement of claim 37, wherein the regular pattern of the capacitors and the regular pattern of the openings of the supporting structure have substantially the same size and geometrical form.

39. The capacitor arrangement of claim 37, wherein the regular patterns are square grids.

40. The capacitor arrangement of claim 37, wherein the supporting structure is arranged adjacent an upper portion of the first electrode.

41. The capacitor arrangement of claim 37, wherein the supporting structure is arranged adjacent a middle portion of the first electrode.
